(19) United States
(12) Patent Application Publication
(10) Pub. No.: US 2007/0166459 A1
(43) Pub. Date: Jul. 19, 2007

(54) Assembly and method for delivering a reactant material onto a substrate

(75) Inventors: Frank P. Chang, San Jose, CA (US); Henry Ho, San Jose, CA (US); Shulin Wang, Campbell, CA (US); Li Fu, San Francisco, CA (US); Qing Lv, Shanghai (CN)

Correspondence Address: WELLS ST. JOHN P.S., 601 W. FIRST AVENUE, SUITE 1300, SPOKANE, WA, 99201, US

(73) Assignee: Advanced Micro-Fabrication Equipment, Inc.

(21) Appl. No.: 11/361,950

(22) Filed: Feb. 23, 2006

(30) Foreign Application Priority Data
Jan. 16, 2006 (CN) 200610023328.0

(51) Int. Cl. C23C 16/00

(52) U.S. Cl. 427/255.5; 118/719; 427/248.1

(57) ABSTRACT

An assembly and method for delivering a reactant material onto a substrate is described and which includes a delivery member which has a first surface, and an opposite second surface, and wherein the second surface is positioned adjacent to a substrate, and wherein an elongated substantially continuous channel is formed in the second surface of the delivery member, and which is coupled in fluid flowing relation relative to a source of reactant material, and wherein the elongated substantially continuous channel delivers the reactant material onto the substrate.

### RELATED PATENT DATA

This application claims priority from Chinese Patent Application Serial No. 200610023328.0, and which was filed on Jan. 16, 2006.

### TECHNICAL FIELD

The present invention relates to an assembly and method for delivering a reactant material onto a substrate, and more specifically to an assembly which delivers gaseous chemicals to a surface for purposes of depositing uniform films or layers on the surface by chemical vapor deposition or the like.

### BACKGROUND OF THE INVENTION

Chemical vapor deposition (CVD) is a critical manufacturing step in semiconductor fabrication. This process occurs when stable compounds are formed by a thermal reaction or deposition of certain gaseous chemicals, and such resulting compounds are deposited onto a surface of a semiconductor wafer. The prior art is replete with numerous examples of devices such as seen in U.S. Pat. Nos. 5,683,516; 6,022,414; and 6,387,764, and which are useful for depositing uniform layers of various materials onto a semiconductor wafer.

While these various assemblies have worked with varying degrees of success, the current prior art practice is to move the semiconductor wafer as close as possible to an associated showerhead, or injector such as disclosed in the above referenced patents to increase the quality of the resulting films that are deposited on the semiconductor wafer. However, as these distances between the semiconductor wafer and the associated showerhead or injector decrease, increasing showerhead temperature as well as temperature variations across the surface area of the showerhead occasionally occur, from wafer to wafer, resulting in a decrease in the uniformity of the resulting layers deposited on the semiconductor wafer and the formation of polymers which generate particles. Still further, in the use of various showerhead designs which have been typically employed heretofore, various chemicals have been mixed within the showerhead and then exit the showerhead to be deposited as a film or layer on the closely adjacent semiconductor wafer. However, in these arrangements, polymerization may sometimes occur within the showerhead which may result in less than desirable step coverage or imperfections in the layer or film material being deposited.

Therefore, an assembly for delivering a reactant material to a substrate and which avoids the shortcomings attendant with the prior art methodology and practices utilized heretofore, is the subject matter of the present application.

### SUMMARY OF THE INVENTION

A first aspect of the present invention relates to an assembly for delivering a reactant material to a substrate which includes a delivery member which has a first surface, and an opposite second surface, and wherein the second surface is positioned adjacent to a substrate, and wherein an elongated substantially continuous channel is formed in the second surface of the delivery member, and which is coupled in fluid flowing relation relative to a source of the reactant material, and wherein the elongated substantially continuous channel delivers the reactant material to the substrate.

Still another aspect of the present invention relates to an assembly for delivering a reactant material to a substrate, and which includes a pedestal which rotatably supports a substrate in a substantially horizontal orientation; and a delivery member having a main body which is defined by a central region, and a peripheral edge, and wherein the delivery member defines a plurality of elongated reactant delivery channels which each have a first end which is located in the central region of the delivery member, and which are each coupled with a source of reactant material, and an opposite second end which is located near the peripheral edge of the main body, and wherein the respective reactant delivery channels are dimensioned so as to deliver a variable amount of the respective reactant materials along the length of the respective reactant delivery channels, and wherein the plurality of reactant delivery channels are located in proximity to each other so as to facilitate the chemical reaction of the respective reactant materials to form a product which is delivered in a substantially uniform fashion to a surface of the rotating substrate.

Still another aspect of the present invention relates to an assembly for delivering a reactant material to a rotating substrate which includes a plurality of reactant materials which when chemically reacted together form a resulting product which is delivered to a surface of a rotating substrate; and a delivery member coupled in fluid flowing relation relative to the respective reactant materials, and positioned above the rotating substrate, and wherein the delivery member delivers the respective reactant materials into a chemical reaction zone which is located therebetween the delivery member and the rotating substrate, and in a manner where the resulting product is chemically produced in the chemical reaction zone following the release of the reactant materials from the delivery member, and wherein the delivery member is arranged so as to deliver a variable amount of reactant materials which results in the generation of an amount of the resulting product which is correlated to the speed of rotation of a region of the rotating substrate which is positioned therebeneath the delivery member to cause a substantially uniform deposition of the resulting product on the surface of the rotating substrate.

A further aspect of the present invention relates to an assembly for delivering a reactant material to a substrate which includes a fluid delivery member having a main body defined by a first surface, an opposite second surface, and a peripheral edge, and wherein the first surface defines a substantially centrally disposed reactant delivery region which is coupled in fluid flowing relation relative to a plurality of reactants which are to be delivered by the fluid delivery member to a chemical reaction zone which is located adjacent to the second surface of the fluid delivery member, and wherein the first surface is further defined by a plurality of structural members which extend radially outwardly relative to the centrally disposed reactant delivery region to the peripheral edge of the main body, and wherein a plurality of passageways are formed in the intermediate regions and which facilitate the passage of a source of gas therethrough, and wherein a fluid distribution passageway is formed in each of the plurality of structural members, and wherein the fluid distribution passageway has a first end which is coupled in fluid flowing relation relative the centrally disposed reactant delivery region, and an opposite second end which is located near the peripheral edge, and wherein the fluid distribution passageway extends in an acutely angulated orientation therebetween the centrally disposed reactant delivery region, and the peripheral edge, and wherein the first end of the fluid distribution passageway is located near the first surface of the main body, and the second end of the fluid distribution passageway is located near the second surface thereof, and wherein an elongated slot having a variable depth, is formed in the second surface of the main body, and which individually couples the fluid distribution passageway in fluid communication with the second surface, and wherein the elongated slot has a depth dimension which diminishes when measured from the first end of the fluid distribution passageway, in the direction of the second end of the fluid distribution passageway, and wherein reactants delivered to the centrally disposed reactant delivery region pass into the first end of the fluid distribution passageway, and then through the elongated slot, for subsequent delivery into the chemical reaction region which is located adjacent to the second surface.

Still further, the present invention relates to a method for depositing a reactant material onto a surface of a substrate, and which includes the steps of providing a rotating pedestal which supports a substrate in a substantially horizontal and rotational orientation; providing sources of reactant materials which when chemically reacted together form a resulting product which is deposited onto the surface of the substrate; providing a delivery member which has a plurality of elongated reactant delivery channels formed therein, and coupling the delivery member in fluid flowing relation relative to the sources of reactant materials; positioning the substrate in spaced, rotating relation relative to the delivery member, and wherein a chemical reaction zone is defined therebetween the surface of the substrate and the delivery member; and delivering a variable amount of the reactant materials by way of the elongated reactant delivery channels into the chemical reaction zone to produce an amount of the resulting product which is substantially uniformly deposited on the surface of the rotating substrate.

Another aspect of the present invention relates to an assembly for delivering a reactant material to a substrate, and which includes a delivery member having opposite first and second surfaces, and wherein the second surface is positioned adjacent to a substrate, and wherein a substantially continuous fluid distribution passageway is formed in the delivery member and is further coupled in fluid flowing relation relative to a source of reactant material, and wherein a plurality of reactant delivery passageways are formed in the second surface and extend in the direction of the first surface, and which are coupled in fluid flowing relation relative to the substantially continuous fluid distribution passageway, and wherein the respective reactant delivery passageways deliver the reactant material in amounts which facilitate a deposit of a substantially uniform amount of the reactant material on the adjacent substrate.

These and other aspect of the present invention will be described in greater detail hereinafter.

### BRIEF DESCRIPTION OF THE DRAWINGS

Preferred embodiments of the invention are described below with reference to the following accompanying drawings.

FIG. 1 is a first perspective, side elevation view of a portion of the assembly for delivering a reactant material of the present invention.

FIG. 2 is a second perspective, side elevation view of a portion of the assembly for delivering a reactant material of the present invention.

FIG. 3 is a fragmentary, greatly enlarged, side elevation view of a portion of the assembly for delivering a reactant material to a substrate, and which is taken form a position along line 3-3 of FIG. 1.

FIG. 4 is a transverse, vertical, sectional view taken from a position along line 4-4 of FIG. 1.

FIG. 5 is a fragmentary, greatly enlarged, transverse, vertical, sectional view taken from a position along line 5-5 of FIG. 1.

FIG. 6 is a perspective, fragmentary, transverse, vertical, sectional view taken from a position along line 7-7 of FIG. 3.

FIG. 7 is a greatly simplified schematic view of a chemical vapor deposition chamber incorporating the teachings of the present invention.

FIG. 8 is a greatly enlarged, fragmentary, somewhat simplified transverse, vertical, sectional view taken from a position along line 8-8 of FIG. 1, and which shows one arrangement of a plurality of continuous channels which form a feature of the present invention.

FIG. 9 is a greatly enlarged, fragmentary, somewhat simplified transverse, vertical, sectional view taken from a position along line 8-8 of FIG. 1, and which shows a second arrangement of a plurality of continuous channels which form another feature of the present invention.

FIG. 10 is a greatly enlarged, fragmentary, somewhat simplified transverse, vertical, sectional view taken from a position along line 8-8 of FIG. 1, and which shows a third possible arrangement of a plurality of continuous channels which form another feature of the present invention.

FIGS. 11A-FIG. 11D are greatly simplified, fragmentary, transverse, vertical, sectional views of several alternative, continuous channel shapes which are useful in the practice of the present invention.

FIGS. 12A and 12B are greatly simplified, fragmentary, transverse, vertical, sectional views of alternative purging gas passageway shapes which are features of the present invention.

FIG. 13 is a greatly simplified, fragmentary, transverse, vertical, sectional view of a second form of a delivery member of the present invention.

FIG. 14 is a second, fragmentary, transverse, vertical, sectional view of second form of a delivery member of the present invention.

FIGS. 15A and 15B are greatly simplified, fragmentary, transverse, vertical, sectional views of two alternative forms of a third embodiment of the present invention.

FIG. 16 is a greatly simplified, fragmentary, transverse, vertical, sectional view of yet another, alternative embodiment of the present invention.

FIG. 17 is a perspective, side elevation view of a portion of an alternative form of the present invention.

FIG. 18 is a perspective, side elevation view of a portion of yet another alternative form of the present invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

An assembly for delivering a reactant material to a substrate and which is further useful in practicing the methodology of the present invention is best understood by the greatly simplified view as seen in FIG. 7. As seen therein, an assembly for delivering a reactant material to a substrate is generally indicated by the numeral 10. The assembly 10 is incorporated or otherwise positioned within a chemical vapor deposition chamber, and which is designated by the numeral 11. The CVD chamber 11 has a wall 12, which defines an internal chamber 13, and which receives, and processes a substrate or semiconductor wafer which is designated by the numeral 14. In the arrangement as seen in FIG. 7, the CVD chamber 11 has a top surface 15, and a plurality of reactant materials which are generally indicated by the numerals 20, 21 and 22, respectively, are coupled in fluid flowing relation relative to the assembly 10. As should be understood, various valve and other control assemblies (not shown) are typically utilized to meter these reactant materials in various amounts to the assembly 10. As seen in FIG. 7, a support member or pedestal is utilized to support the semiconductor wafer 14 in a substantially horizontal orientation therebetween the assembly 10 and the pedestal 23. The pedestal or support member can be fabricated to include a heating element which is selected from the group comprising a resistive heating element; a coil inductive heating element; a lamp heating element and other heating means which are operable to impart heat energy to the semiconductor wafer 14. The pedestal is arranged so as to rotate the semiconductor wafer 14 at a predetermined rotational speed. The semiconductor wafer is positioned within a chemical reaction zone 24 which is positioned therebetween the assembly 10 and the pedestal 23. It should be understood that the present invention may be employed in a single chamber arrangement such as illustrated in FIG. 7, or a multiple work station chamber where several substrates 14 are processed substantially simultaneously in the different work stations. As will be described in greater detail hereinafter, one aspect of the present invention 10 includes a method for depositing a reactant material such as 20, 21 and/or 22 onto a surface 25 of a substrate, such as a semiconductor wafer 14. The methodology broadly includes the steps of providing a rotating pedestal 23 which supports a substrate such as a semiconductor wafer 14 in a substantially horizontal and rotational orientation; and providing sources of reactant materials 20, 21 and 22, which, when chemically reacted together, form a resulting product which is deposited onto the surface 25 of the substrate 14. The methodology of the present invention includes further steps of providing a delivery member, such as 10, which has a plurality of elongated reactant delivery channels and/or reactant delivery passageways formed therein, and which will be discussed in greater detail hereinafter, and coupling the delivery member 10 in fluid flowing relation relative to the sources of reactant materials 20, 21 and 22. As seen in FIG. 7, the methodology includes a further step of positioning the substrate such as a semiconductor wafer 14 in spaced, rotating relation relative to the delivery member 10, and wherein a chemical reaction zone 24 is defined therebetween the surface 25 of the substrate 14, and the delivery member 10. The methodology includes yet another step of delivering a variable amount of the reactant materials 20, 21 and 22 by way of the elongated reactant delivery channels, and/or reactant delivery passageways, as will be described below, into the chemical reaction zone 24 to produce an amount of a resulting product which is substantially uniformly deposited on the surface 25 of the rotating substrate 14. The present invention comprises several embodiments with different inventive features. Common elements of each inventive embodiment will be identified by similar numbers.

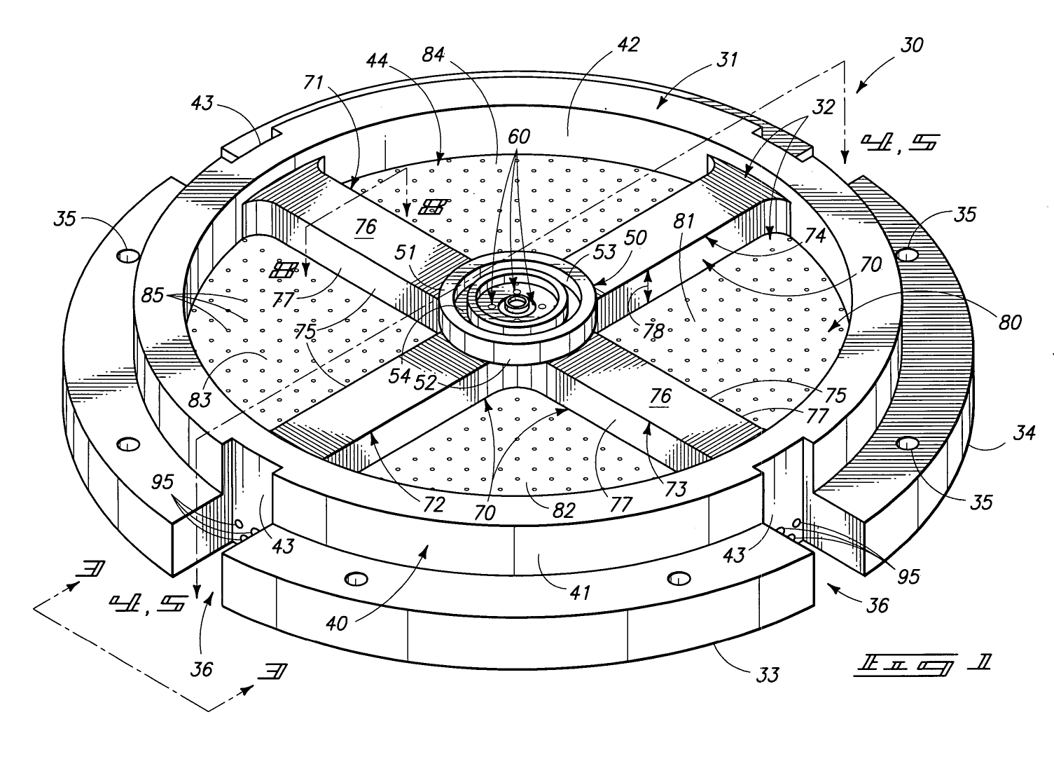

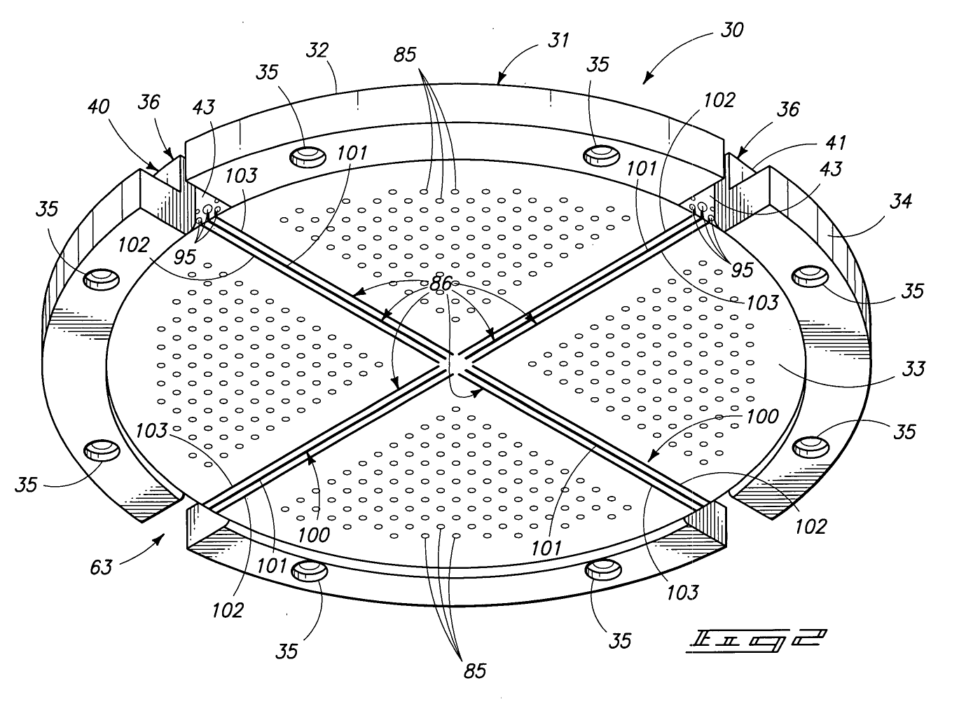

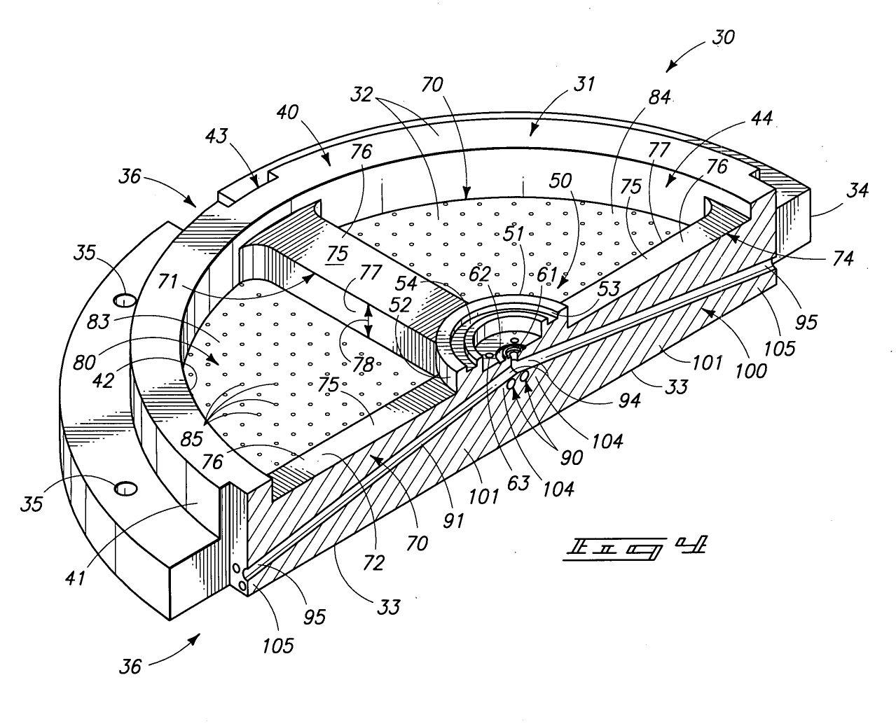

Referring now to FIGS. 1-6, for example, it will be seen that a first form of an assembly for delivering a reactant material to a substrate 10 includes a delivery member which is generally indicated by the numeral 30, and which is coupled in fluid flowing relation relative to the plurality of reactant materials or chemicals which are generally indicated by the numerals 20, 21 and 22, in FIG. 7. The delivery member 30, includes a main body 31 which has a first, outwardly facing surface 32 (FIG. 1); and a second inwardly facing surface 33 (FIG. 2). Still further, the main body 31 is defined by a peripheral edge 34. As seen in FIG. 1, and following, a plurality of mounting holes 35 are formed in the peripheral edge, and are operable to receive fasteners (not shown) which extend therethrough and which support or otherwise secure the delivery member 30 in a fixed position on the top surface 15 of the CVD chamber 11 as seen in FIG. 7. Still further, and positioned at predetermined locations about the peripheral edge 34, are individual notched regions 36, the importance of which will be discussed in greater detail, hereinafter. As seen in FIG. 10, and in an alternative form of the invention, a reaction cavity 37 may be formed in the second surface 33 and which facilitates the chemical reaction of the reactant materials 20, 21 and 22 when they are delivered by the delivery member 30 to the chemical reaction zone 24 as seen in FIGS. 7 and 10, respectively.

Still referring to FIGS. 1-6, 14, 17 and 18 it will be seen that the main body 31 is depicted herein as substantially circular in its overall configuration. However, it will be appreciated that the main body 31 may be formed in various shapes other than in circular configuration as depicted herein. However, as seen in FIGS. 1-7, 14, 17 and 18, it will be appreciated that the main body 31, and more specifically the first surface 32 thereof, includes a substantially vertically oriented and substantially circumscribing flange member 40 which is positioned in radially inwardly spaced relationship relative to the peripheral edge 34. The circumscribing flange 40 has a first outwardly facing surface 41,and an opposite second inwardly facing surface 42. Still further, and as seen in the drawings, individual notched regions 43 are formed in the first outwardly facing surface 41 and are operable to matingly cooperate, or otherwise vertically align with the notched regions 36 which are formed in the peripheral edge 34. As will be appreciated from FIGS. 1, and following, an internal cavity 44 is defined by the second.

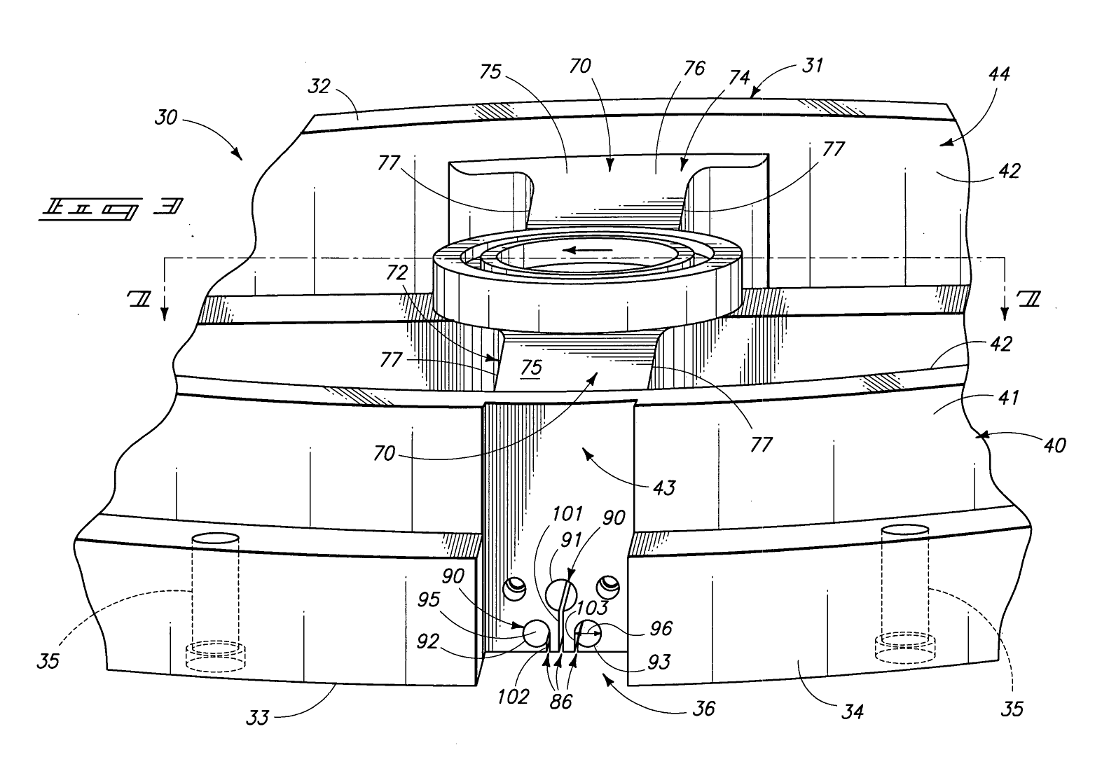

Referring now to FIGS. 1, 4, 5, 6 and 14, it will be seen that the assembly for delivering a reactant material 10 of the present invention includes, as a feature of the first outwardly facing surface 32, a substantially centrally disposed reactant delivery region which is generally indicated by the numeral 50. While this reactant delivery region is depicted in the drawings as being circular in its configuration, other shapes will work with equal success. As seen in the views mentioned above, the reactant delivery region 50 has a main body 51 which has an outwardly facing surface 52, and an opposite inwardly facing surface 53. As seen in FIG. 1 for example, a circumscribing channel 54 is formed in the main body 51 and is operable to receive a suitable seal which will sealably couple the reactant delivery region 50 to conduits delivering the reactant material sources 20, 21 and 22, respectively, and also thereagainst the top surface 15 of the chemical vapor deposition chamber 11 as seen in FIG. 7. As will be appreciated from a study of FIGS. 1, 4, 5 and 6, the centrally disposed reactant delivery region 50 is defined by a plurality of reactant material passageways which are generally indicated by the numeral 60. The reactant material passageways 60 are coupled in fluid flowing relation relative to the source of reactant materials 20, 21 and 22 as earlier discussed. The reactant material passageways include first, second and third passageways 61, 62 and 63, respectively (FIG. 4), and which are coupled in fluid flowing relation relative to elongated substantially uniformly dimensioned bores or fluid distribution passageways which will be discussed in greater detail, hereinafter.

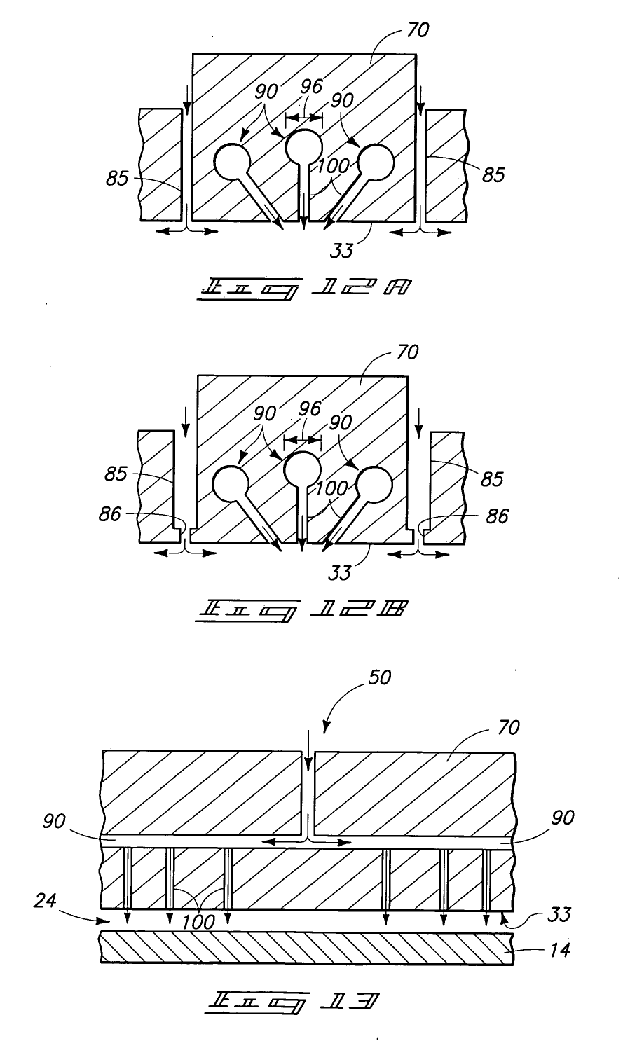

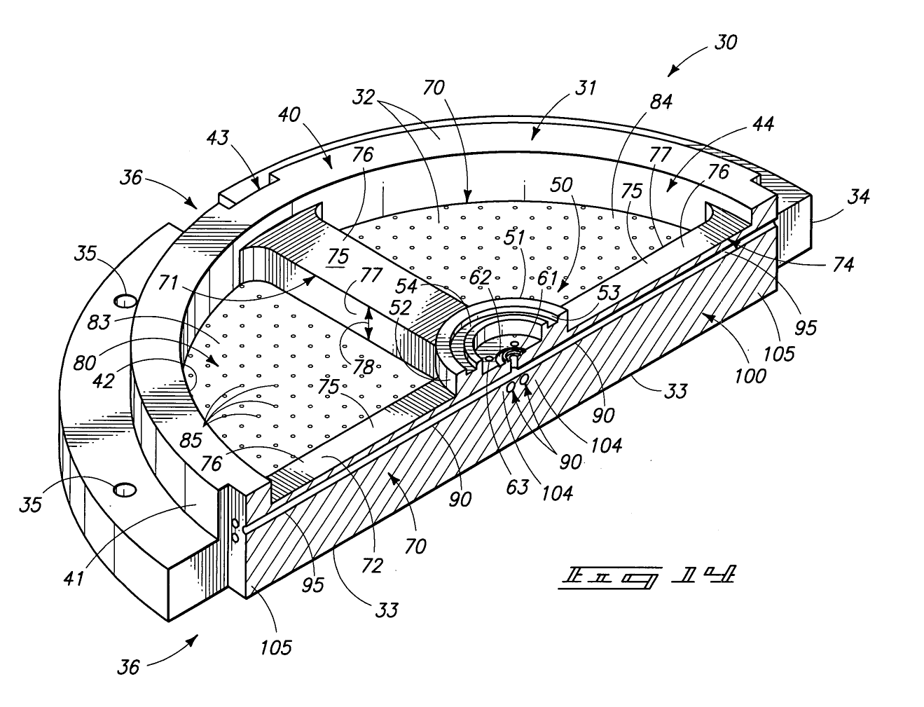

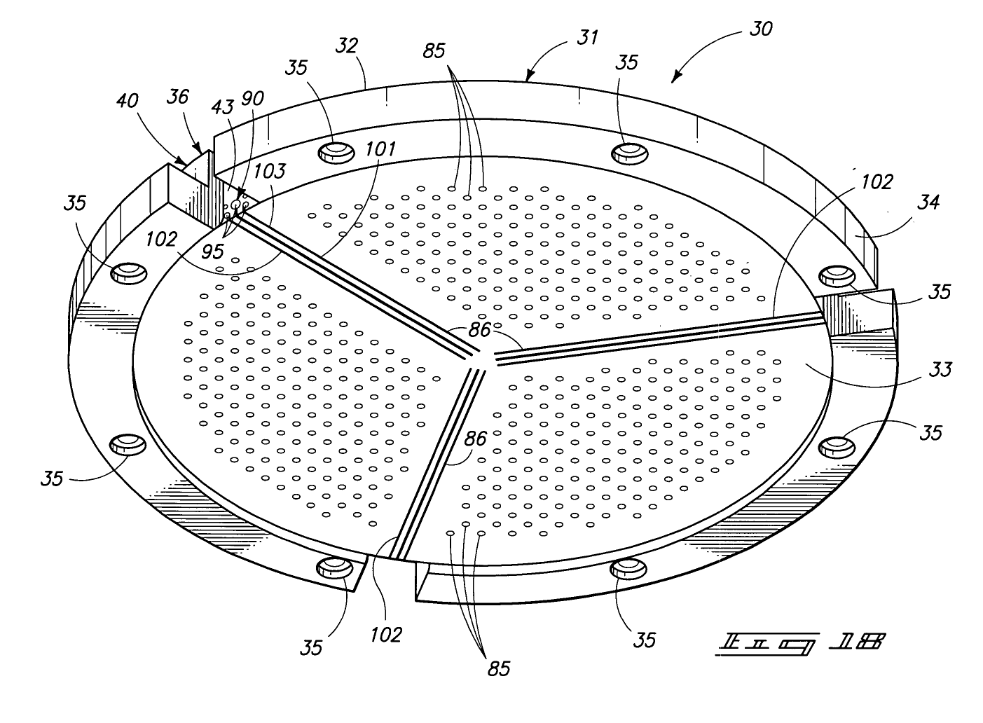

Referring now to FIG. 1 and 4, for example, the assembly for delivering a reactant material 10 of the present invention includes, as a feature of the first outwardly facing surface 32, a plurality of structural members which are generally indicated by the numeral 70, and which extend, in this form of the invention, generally radially outwardly relative to the centrally disposed reactant delivery region 50 to the peripheral edge 34 of the main body 31. As seen in FIG. 1 and following, the plurality of structural members 70 include first, second, third and fourth members 71-74, respectively, and which are positioned at substantially equally spaced orientations, one relative to the others. As will be appreciated from a study of the FIGS. 17 and 18, which show two other alternative forms of the invention, the delivery member 30 may be fabricated to include only two structural members, which are substantially coaxially aligned with each other (FIG. 17); or three structural members which are disposed in spaced, substantially 120 degree offset relation one relative to the others (FIG. 18). Each of the structural members include a main body 75 which extends from the outwardly facing surface 52 of the centrally disposed reactant delivery region 50 to the second inwardly facing surface 42 of the circumscribing flange member 40 (FIG. 1). Further, the main body 75 includes a top surface 76, and a pair of opposite, substantially parallel sidewalls 77. As will be appreciated, the main body 75 of the respective structural members 70 has a height or thickness dimension indicated by the line labeled 78 (FIG. 1). Additionally, and still referring to FIG. 1, the first outwardly facing surface 32 includes intermediate regions 80 which are positioned therebetween the respective structural members 70. The intermediate regions are identified by first, second, third and fourth regions 81-84, respectively. As seen in the drawings, a plurality of passageways 85 extend therethrough the intermediate region, and provide a gaseous passageway which allows a purging or cleaning gas to travel therethrough in order to render the present assembly 10 useful in a chemical vapor deposition environment (FIG. 7). For example, when the assembly 10 is used in a deposition mode, purge gas, such as N₂ can be delivered to the passageways 85 to prevent particle formation and deposition onto the intermediate regions of the second surface 33 of the delivery member 30. Further, when cleaning the assembly 10 a cleaning gas, such as NF₃ can be delivered to both the passageways 85, and the substantially elongated channels 86. As will be appreciated by a study of FIG. 4, it will be understood that the respective intermediate regions 80 each have a thickness dimension which is less than the thickness dimension 78 of the respective structural members 70. Other thickness dimensions for the intermediate regions 80 will also work with equal success. As seen in FIG. 12A, the passageways 85 may have a substantially uniform, transverse, or diametral dimension along its entire length. On the other hand, and as seen in FIG. 12B, the passageways may have a variable, transverse, or diametral dimension such as by having a reduced dimension region 86. Of course, the passageways may include a mixture or both types of passageways as seen in FIGS. 12A and B, respectively.

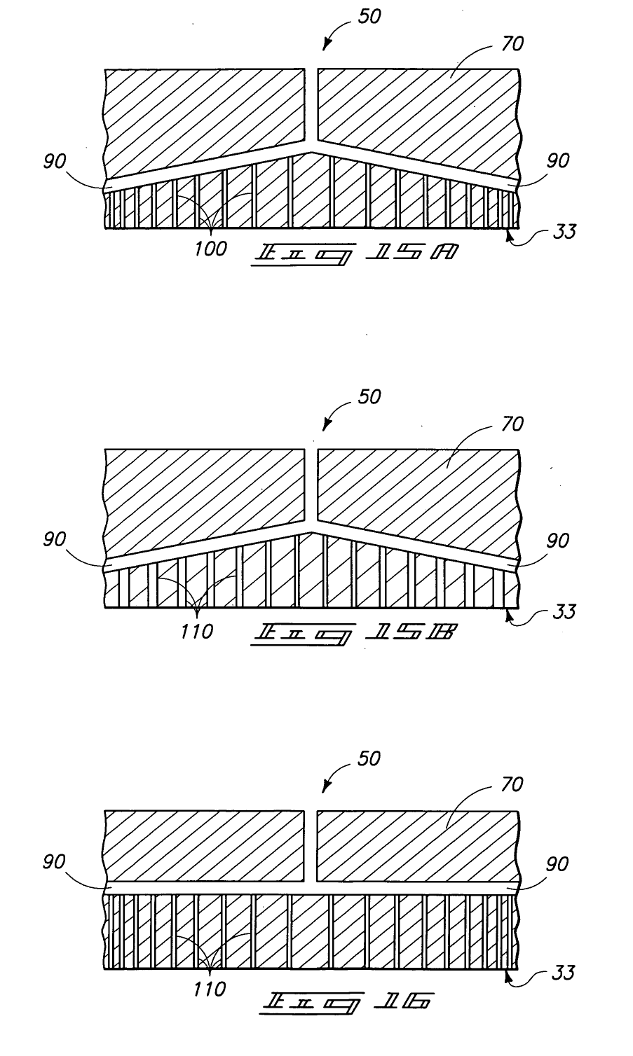

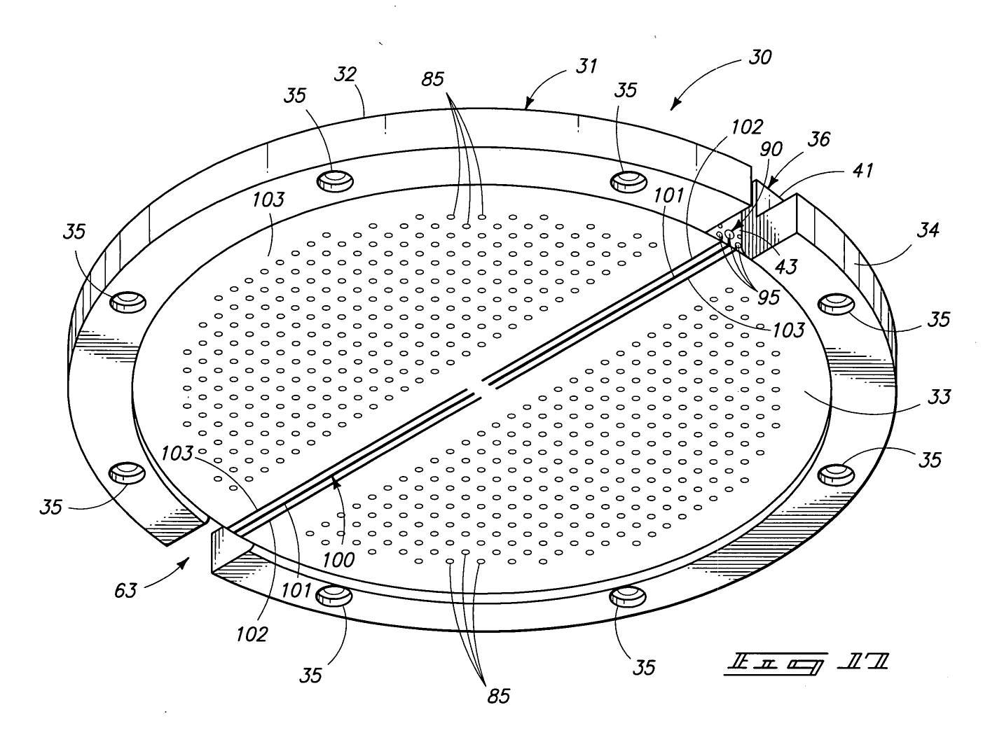

As seen by reference to FIGS. 4 and 5, for example, it should be understood that the assembly 10 of the present invention includes a plurality of elongated substantially continuous channels 86 which are formed in the second surface 33 of the delivery member 30 (FIG. 2), and which are coupled in fluid flowing relation relative to the sources of reactant materials 20, 21 and 22. FIG. 2 depicts one possible arrangement of the substantially continuous channels, and wherein complementary groups of channels 86 are disposed in equally spaced relation about the second surface 33. However, as seen in FIG. 17 and 18, other arrangements are possible, and these other arrangements are deemed to be within the scope of the present invention. The substantially continuous channels 86 comprise a plurality of bores or fluid distribution passageways which are generally indicated by the numeral 90, and which are indicated as first, second and third fluid distribution passageways 91, 92 and 93 (FIG. 3) which are formed in each of the structural members 70 and which extend, in one form of the invention, in an acutely angulated orientation therebetween the centrally disposed reactant region 50, and the peripheral edge 34 of the main body 31 (FIG. 4). In this regard, the respective fluid distribution passageways, depending on the form of the invention, each have an angular orientation relative to the second surface 33 which lies in a range of about 0 degrees to less than about 60 degrees. An example of a form of the invention having fluid distribution passageways 90 which are disposed in a substantially parallel, spaced relationship relative to the second surface is seen in FIG. 14 and 16. Further, other forms of the invention having fluid distribution passageways 90 in an acutely angulated orientation of less than about 60 degrees relative to the second surface 33 are seen in FIGS. 4, 15A and 15B, respectively. Each of the fluid distribution passageways 91-93 has a first end 94 which is located in the centrally disposed reactant delivery region 50, and which is coupled in fluid flowing relation relative to the individual reactant materials 21-23, respectively, and an opposite second end 95 which is located near the peripheral edge 34. As seen in FIG. 5, the first end 94 of the respective fluid distribution passageways 90 are located near the first surface 32, and the second end 95 is located near the second surface 33. As illustrated most clearly by reference to FIG. 3, each of the fluid distribution passageways 90 is defined by an inside diametral dimension 96. As illustrated in FIG. 5, the respective inside diametral dimensions of the fluid distribution passageways 91-93, are different. However, in certain forms of the invention, the inside diametral dimensions may be of similar dimensions. As should be understood, the inside diametral dimensions of the respective fluid distribution passageways 91-93 are selected based upon the type of reactant material 20-22 which is supplied through same. As seen in FIG. 5, for example, it will be understood that the first, second and third fluid distribution passageways 91, 92 and 93, respectively are individually coupled in fluid flowing relation relative to the first, second and third passageways 61, 62 and 63 which are defined by the centrally disposed reactant delivery region 50. As should be understood, the first, second and third passageways 61, 62 and 63 may be bifurcated in various ways so as to supply a selected reactant material 20, 21 and 22 to more than one fluid distribution passageway 90 substantially simultaneously.

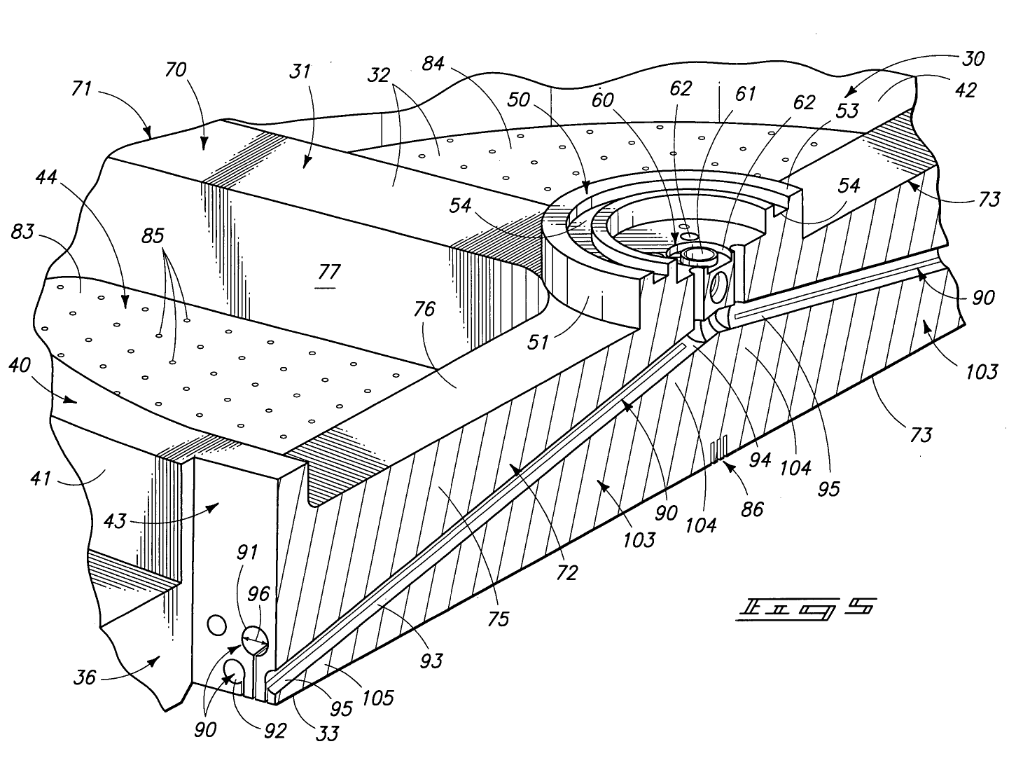

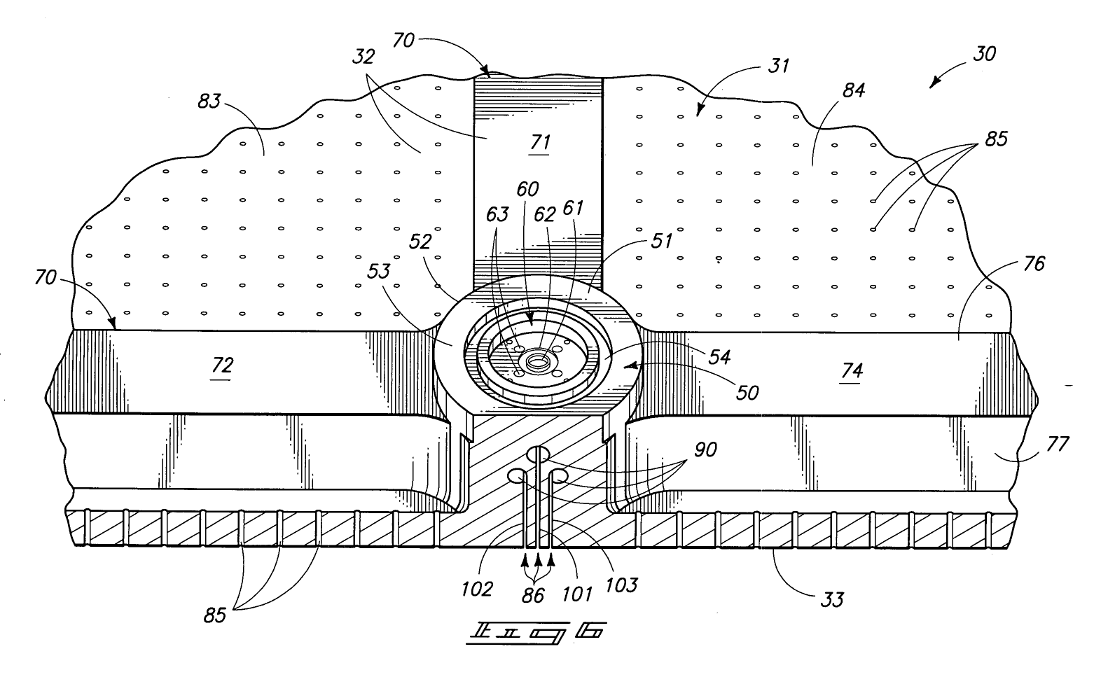

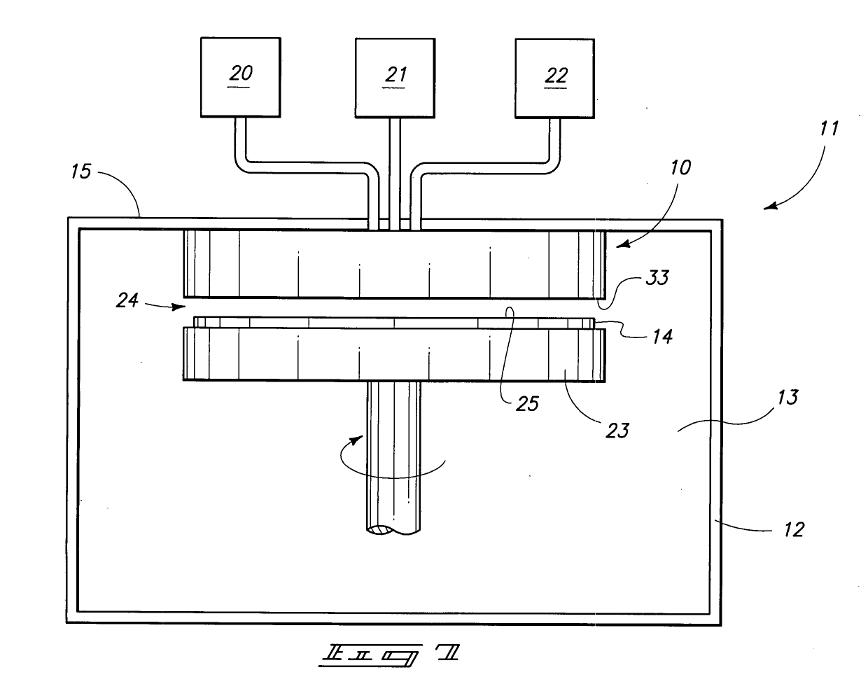

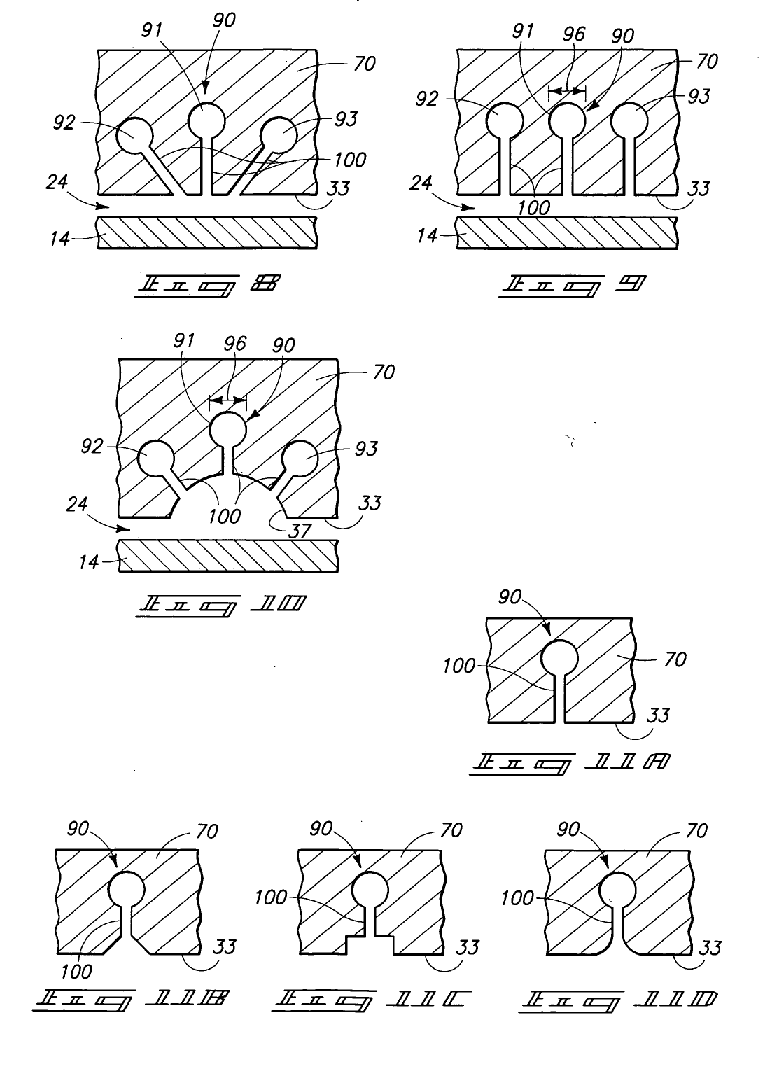

Referring now to FIGS. 2 and 3, for example, it will be seen that the assembly 10 of the present invention, and more specifically the substantially elongated channels 86 further includes a plurality of elongated slots which are generally indicated by the numeral 100, and which are formed in the second surface 33 of the main body 31 and which are further coupled in fluid communication relative to each of the respective fluid distribution passageways 90. As best illustrated by reference to FIGS. 8-10,11A-D; 12A and 12B, the respective slots 100 which are coupled in fluid flowing relation relative to the fluid distribution passageway 90 may have a transverse or width dimension which is substantially uniform along its length (FIG. 11A, 12A and 12B, for example); or a non-uniform dimension (FIGS. 11B, C and D). Still further, and as seen in FIGS. 8-10, the respective elongated slots may have an angular orientation relative to the second surface 33 which lies in range of about 45 degrees (FIG. 8) to about 90 degrees (FIG. 9). As illustrated in FIG. 10, and in one form of the invention, the respective slots are coupled in fluid flowing relation relative to the reaction cavity 37 which is formed in the bottom surface 33 of the delivery member 30. As seen in FIG. 13 and 14, the elongated slot 100, in one form of the invention, has a substantially uniform depth dimension when that is measured along its entire length. As seen in the drawings, the elongated substantially continuous slots 100 are identified as first, second and third slots 101-103, respectively (FIG. 3). Each of the elongated slots or channels 100 has a first end 104, and an opposite second end 105 (FIG. 4). As seen in FIG. 4, the first end 104 of the substantially elongated slots 100 is located in the centrally disposed reactant delivery region 50, and the second end 105 is typically located near, or adjacent to, the peripheral edge 34. As should be understood, the elongated substantially continuous slots 100 are each coupled in fluid flowing relation relative to the source of reactant materials which may comprise first, second or third reactant materials 20, 21 and 22, respectively, depending upon the specific fluid distribution passageway 90 with which the slot 100 is connected. As seen in FIG. 2, 3 and 4, the respective elongated substantially continuous slots 100 are located in closely adjacent spaced relation, one relative to the others. Further, in one form of the invention, as seen for example in FIG. 4, each of the slots 100 has a variable depth dimension when measured from the second surface 33. As illustrated in the drawings, the elongated substantially continuous slots 100 extend radially outwardly from the centrally disposed reactant delivery region 50, and are coupled in fluid flowing relation along the entire length of each of the elongated fluid distribution passageways 90. In operation, and as will be discussed in greater detail hereinafter, the plurality of reactant materials 20, 21 and 22, respectively, exit the respective elongated substantially continuous slots 100 to form a product within the chemical reaction zone 24 and which is subsequently deposited on a substrate such as a semiconductor wafer 14 which is supported on the pedestal 23.

As seen by reference to FIG. 4, which represents only one of several forms of the invention, the elongated slots 100 each have a depth dimension which diminishes when measured from the first end 104 of each of the substantially continuous slots in the direction of the peripheral edge 34 or second end 105. As best appreciated by a study of FIG. 2, the width of the respective elongated slots 100 is substantially constant. However, it should be appreciated that the width dimension of the respective slots may be varied. More specifically, the first, second and third slots 101 -103 may have different width dimensions depending upon the reactant material which exits same. Still further, in yet another possible form of the invention, the respective slots 100 may have a continuously variable width dimension when measured from the central region 50 in the direction of the peripheral edge 34. This alternative arrangement of having a slot 100 with a continuously variable width dimension is particularly useful when the depth dimension of the slot 100 is substantially constant as illustrated in FIG. 14. Therefore, the depth and width dimensions of the respective slots may be the same, different, or in various combinations based upon the reactant materials 20-22 which are being supplied by the assembly 10. In any event, however, the depth and width dimensions of the respective slots 100 are selected so as to provide an appropriate amount of each of the respective reactants 20, 21 and 22 into the chemical reaction zone 24 to facilitate a chemical reaction which produces a resulting product which is then deposited substantially uniformly onto the surface 25 of the supporting substrate herein indicated as a semiconductor wafer 14. The amount of reactant material supplied, or emitted from the various regions, and along the length of the respective elongated slots 100 is selected so as to be correlated with the speed of rotation of the underlying substrate 14 which is being rotated by the pedestal 23. Stated in yet another way, it will be understood that the outer peripheral edge of the substrate or semiconductor wafer 14 rotates at a different and higher speed relative to the middle or central portion of same. Consequently, the tapering or diminishing depth dimension, or profile, of the respective elongated slots 100 are selected so as to deliver a variable amount of reactant materials 20-22. These reactant materials, when chemically reacted, produce an amount of a resulting product which provides a substantially uniform coverage or film onto the underlying semiconductor wafer 14 at the speed of rotation of the semiconductor substrate 14 which is located therebeneath the assembly 10. As noted above, each of the elongated slots 100 may have similar or dissimilar dimensions based upon the nature of the reactant material being supplied.

In another form of the invention as seen in FIG. 15A, a plurality of discrete reactant delivery passageways 110 replace the aforementioned slots 100. In this regard, the respective reactant delivery passageways 110 are formed in the second surface 32 and which are coupled in fluid flowing relation relative to the continuous fluid distribution passageway 90. As should be understood, the respective reactant delivery passageways deliver the reactant materials 20, 21 and 22 in amounts which facilitate a deposit of a substantially uniform amount of the reactant material, or a resulting by-product formed from the chemical reaction of the reactant materials, onto the adjacent rotating substrate 14. As seen in FIG. 15A and 16, the plurality of reactant delivery passageways 110 may each have a substantially similar or uniform transverse, or inside diametral dimension when this is measured along the length of same. When reactant delivery passageways 110 of this form of the invention are employed, it will be seen that the distance between the respective similarly dimensioned reactant delivery passageways 110 decrease when those distances are measured from the central region 50, and in the direction of the peripheral edge 34. With respect to FIGS. 15A and 16, it will be recognized that the length dimension of the respective reactant delivery passageways may be substantially similar (FIG. 16); or further may diminish in length as that is measured from the central region 50, and in the direction of the peripheral edge 34 (FIG. 15A). In yet another form of the invention as seen in FIG. 15B, the respective reactant delivery passageways 110 may have dissimilar transverse, or inside diametral dimensions. In this form of the invention, it will be recognized that the transverse or inside diametral dimension of the respective reactant delivery passageways 110 increase when that dimension is measured from the central region 50, and in the direction of the peripheral edge 34. This arrangement facilitates the delivery of reactant materials 20, 21, and 22 in amounts which are correlated to the speed of rotation of the substrate 14 which is located therebeneath so as to provide a resulting substantially uniform coating.

### Operation

The operation of the described embodiment of the present invention is believed to be readily apparent and is briefly summarized at this point.

As seen in the drawings, it will be understood that an assembly for delivering a reactant material to a substrate 10 includes, in one form of the invention, a support member, here shown as a pedestal 23 having an upwardly facing surface and which rotatably supports a substrate, here illustrated as a semiconductor wafer 14, for processing. Still further, the assembly 10 includes a delivery member 30 having a main body 31 defined by a peripheral edge 34, and which has a first surface 32, and an opposite second surface 33. In the arrangement as seen in FIG. 7, the second surface 33 is positioned adjacent to the substrate 14. Still further, an elongated substantially continuous channel 86 is formed in the second surface 33 of the delivery member 30, and is coupled in fluid flowing relation relative to a source of reactant material here indicated by the numerals 20, 21 and 22, respectively. As earlier disclosed, the present assembly 10 is designed so as to deliver the reactant materials into the chemical reaction zone 24 so as to form a product which is deposited substantially uniformly on the surface 25 of the substrate herein indicated as a semiconductor wafer 14.

More specifically, an assembly for delivering a reactant material to a substrate 10 includes, as earlier described a pedestal 23 which rotatably supports a substrate 14 in a substantially horizontal orientation. Still further, the assembly 10 includes a delivery member 30 having a main body 31, and which is defined by a central region 50, and a peripheral edge 34. The delivery member 30 defines a plurality of elongated reactant delivery channels 86 which comprise individual fluid distribution passageways 90, and an associated slot 100. The respective fluid distribution passageways each have a first end 94 which is located in the central region 50 of the delivery member 30, and which are each coupled with a source of reactant material herein indicated by the numerals 20-22, respectively. Still further, each of the fluid distribution passageways 90, which comprise a portion of the respective channels 86, have an opposite second end 95, which is located near the peripheral edge 34 of the main body 31. The respective reactant delivery channels 86 are dimensioned so as to deliver a variable amount of the respective reactant materials along the length of the respective reactant delivery channels. Still further, the plurality of reactant delivery channels 86 are located in proximity to each other so as to facilitate the chemical reaction of the respective reactant materials 20-22 in the chemical reaction zone 24 to form a product which is delivered in a substantially uniform fashion to a surface 25 of the rotating substrate 14. As earlier discussed, the respective elongated reactant delivery channels 86 are formed by the individual fluid distribution passageways 90, and an associated elongated slot 100. The elongated reactant delivery channels deliver an amount of the reactant material 20-22 which is appropriate to the speed of rotation of the substrate 14 which is positioned therebeneath. Still further, the amount of the reactant material 20-22 which is delivered by each of the respective elongated delivery channels 86 increases when measured from the first end 105, and in the direction of the second end 104 of the respective slots 100.

As seen in FIG. 2, the plurality of reactant delivery channels 86 extend substantially radially outwardly from the central region 50 in the direction of the peripheral edge 34 thereof. As earlier described, the substantially elongated reactant delivery channels 86 include a fluid distribution passageway 90 having a substantially constant inside diametral dimension 96; and an elongated slot 100 which communicates with same. The respective elongated slots 100 have a diminishing depth dimension when measured from the first end 104, in the direction of the second end 105 of each of the elongated slots. As earlier discussed, the elongated delivery channels 86 may have similar or dissimilar dimensions. Additionally, it will be understood that the dimensions of the respective fluid distribution passageways 90 and the elongated slots 100 are selected so as to deliver a variable amount of reactant materials 20-22, respectively, which results in the generation of an amount of the resulting product in the chemical reaction zone 24 which is correlated to the speed of rotation of a region of the rotating substrate 14 which is positioned therebeneath the delivery member 30. As earlier noted, this invention causes a substantially uniform deposition of the reactant materials or a resulting product which is formed by the chemical reaction of reactant materials onto the surface of the rotating substrate 14. As seen in the drawings, the delivery member 30 includes a plurality of complementary pairs of substantially continuous, elongated delivery channels 86 which radiate in opposite directions from the central region 50.

The present invention includes a method for depositing a reactant material 20-22 onto a surface of a substrate 14. The present methodology includes the steps of providing a rotating pedestal 23 which supports a substrate 14 in a substantially horizontal and rotational orientation; and further providing sources of reactant materials 20-22 which, when chemically reacted together, form a resulting product which is deposited onto the surface 25 of the substrate 14. The methodology of the present invention includes the further steps of providing a delivery member 30 which has a plurality of elongated reactant delivery channels 86 or passageways 110 formed therein; and coupling the delivery member 30 in fluid flowing relation relative to the sources of reactant materials 20-22. Moreover, the method includes another step of positioning the substrate 14 in spaced, rotating relation relative to the delivery member 30, and wherein a chemical reaction zone 24 is defined therebetween the surface 25 of the substrate 14, and the delivery member 30. Still further, the method includes another step of delivering a variable amount of the reactant materials 20-22 by way of the elongated reactant delivery channels 86 or passageways 110 into the chemical reaction zone 24 to produce an amount of the resulting product which is substantially uniformly deposited on the surface 25 of the rotating substrate 14. In the methodology as described above, the respective reactant delivery channels 86 further comprise an elongated fluid distribution passageway 90 having opposite first and second ends 94 and 95, respectively; and an elongated slot 100 or passageway 110 which is coupled in fluid flowing relation relative to the fluid distribution passageway 90, and wherein the elongated slot 100 or passageway 110 has a depth dimension and/or transverse dimension which facilitates the uniform deposit of the reactant materials 20, 21 and 22 or a resulting product on the rotating substrate 14.

Therefore, it will be seen that the present invention provides a convenient means by which a semiconductor substrate may be processed in a manner not possible heretofore, and which avoids many of the shortcomings attendant with the prior art devices which have been utilized for similar purposes.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

I claim:

1. An assembly for delivering a reactant material to a substrate, comprising:
a delivery member having a first surface, and an opposite second surface, and wherein the second surface is positioned adjacent to a substrate, and wherein an elongated substantially continuous channel is formed in the second surface of the delivery member, and which is coupled in fluid flowing relation relative to a source of the reactant material, and wherein the elongated substantially continuous channel delivers the reactant material to the substrate, and wherein a plurality of purging gas passageways are formed in the delivery member and extend between the first and second surfaces thereof.

2. An assembly as claimed in claim 1, and wherein the delivery member has a main body defined by a peripheral edge, and wherein the elongated, substantially continuous channel has a first end, and an opposite second end, and wherein the main body of the delivery member has a substantially central region, and wherein the first end of the substantially continuous channel is positioned in the central region of the delivery member, and the second end is located adjacent the peripheral edge.

3. An assembly as claimed in claim 2, and further comprising a support member having an upwardly facing surface, and which rotatably supports the substrate in spaced relation relative to the second surface of the delivery member.

4. An assembly as claimed in claim 2, and wherein the substantially continuous channel has a depth dimension which diminishes as it is measured from the first end of the substantially continuous channel, to the second end thereof.

5. An assembly as claimed in claim 2, and wherein the substantially continuous channel has a depth dimension which is substantially uniform as it is measured from the first end to the second end.

6. An assembly as claimed in claim 1, and wherein the substantially continuous channel comprises at least two continuous channels which are oriented in substantially coaxially alignment one relative to the other.

7. An assembly as claimed in claim 1, and wherein the substantially continuous channel comprises at least three continuous channels which are oriented in an offset, spaced, substantially 120 degree orientation one relative to the others.

8. An assembly as claimed in claim 1, and wherein the substantially continuous channel comprises at least four continuous channels which are oriented in an offset, spaced, substantially 90 degree orientation one relative to the others.

9. An assembly as claimed in claim 1, and wherein the substantially continuous channel is formed, at least in part, of a fluid distribution passageway which has an angular orientation relative to the second surface which lies in a range of about 0 degrees to less than about 60 degrees.

10. An assembly as claimed in claim 1, and wherein the substantially continuous channel comprises a plurality of continuous channels which are each formed, at least in part, of a fluid distribution passageway, and wherein the respective fluid distribution passageways each have an angular orientation relative to the second surface which lies in a range of about 0 degrees to less than about 60 degrees.

11. An assembly as claimed in claim 1, and wherein the substantially continuous channel is formed, at least in part, of an elongated slot, and wherein the elongated slot has an angular orientation relative to the second surface which lies in a range of about 45 degrees to about 90 degrees.

12. An assembly as claimed in claim 1, and wherein the substantially continuous channel comprises a plurality of continuous channels which are each formed, at least in part, by an elongated slot, and wherein the respective elongated slots have individual angular orientations relative to the second surface which lies in a range of about 45 degrees to about 90 degrees.

13. An assembly as claimed in claim 11, and wherein a reaction cavity is formed in the second surface, and wherein the plurality of slots are coupled in fluid flowing communication with the reaction cavity.

14. An assembly as claimed in claim 1, and wherein the elongated substantially continuous channel comprises a plurality of elongated channels, and wherein the respective channels are each coupled in fluid flowing relation relative to a source of a reactant material.

15. An assembly as claimed in claim 14, and wherein the respective elongated substantially continuous channels are located in closely adjacent, spaced relation, one relative to the others, and wherein the respective channels each have a variable depth dimension when measured from the second surface.

16. An assembly as claimed in claim 3, and wherein the support member is a resistive heating member.

17. An assembly as claimed in claim 2, and wherein the main body of the delivery member further has a central region, and wherein the substantially continuous channel extends substantially radially outwardly from the central region in the direction of the peripheral edge.

18. An assembly as claimed in claim 17, and wherein the main body of the delivery member has a plurality of substantially continuous channels which are positioned in closely adjacent spaced relationship, one relative to the others, and which further extend from the central region to a location which is closely adjacent the peripheral edge.

19. An assembly as claimed in claim 18, and wherein a plurality of reactant materials are individually coupled in fluid flowing relation relative to each of the plurality of substantially elongated and continuous channels, and wherein the reactant materials exit the respective elongated and substantially continuous channels to form a product which is deposited on the substrate.

20. An assembly as claimed in claim 18, and wherein each of the substantially continuous channels is defined by a fluid distribution passageway having a substantially constant inside diametral dimension, and an elongated slot which communicates in fluid flowing relation relative to the fluid distribution passageway, and which extends from the fluid distribution passageway to the second surface of the delivery member.

21. An assembly as claimed in claim 20, and wherein each of the substantially continuous channels has a first end which communicates in fluid flowing relation relative to the first surface of the delivery member in the central region, and a second end which is adjacent to the peripheral edge, and wherein the sources of reactant materials are individually supplied to the first end of each of the substantially continuous channels.

22. An assembly as claimed in claim 21, and wherein each of the elongated slots has a substantially similar depth dimension which diminishes when measured from the first end of the substantially continuous channels in the direction of the peripheral edge, and a similar and substantially constant width dimension.

23. An assembly as claimed in claim 21, and wherein each of the elongated slots has a different depth dimension which diminishes when measured from the first end of each of the substantially continuous channels, and in the direction of the peripheral edge, and a similar and substantially constant width dimension.

24. An assembly as claimed in claim 21, and wherein each of the elongated slots has a substantially similar depth dimension which diminishes when measured from the first end of the substantially continuous channels, and in the direction of the peripheral edge, and a dissimilar, yet constant width dimension.

25. An assembly as claimed in claim 21, and wherein each of the elongated slots has a diminishing depth dimension when measured from the first end of each of the channels, and in the direction of the peripheral edge, and a width dimension, and wherein the depth and width dimensions of the respective slots are selected so as to provide a substantially uniform delivery of each of the reactants.

26. An assembly as claimed in claim 21, and wherein each of the elongated slots has a different depth dimension which diminishes when measured from the first end, and in the direction of the peripheral edge, and a dissimilar yet substantially constant depth dimension.

27. An assembly as claimed in claim 2, and wherein the purging gas passageways which are formed in the delivery member are coupled in fluid flowing relation relative to a source of a purge gas, or a source of a cleaning gas, and wherein the purge gas and cleaning gas are further coupled in fluid flowing relation relative to the substantially continuous channel.

28. An assembly for delivering a reactant material to a substrate, comprising:
a pedestal which rotatably supports a substrate in a substantially horizontal orientation; and
a delivery member having a main body which is defined by a central region, and a peripheral edge, and wherein the delivery member defines a plurality of elongated reactant delivery channels which each have a first end which is located in the central region of the delivery member, and which are each coupled with a source of reactant material, and an opposite second end which is located near the peripheral edge of the main body, and wherein the respective reactant delivery channels are dimensioned so as to deliver a variable amount of the respective reactant materials along the length of the respective reactant delivery channels, and wherein the plurality of reactant delivery channels are located in proximity to each other so as to facilitate the chemical reaction of the respective reactant materials to form a product which is delivered in a substantially uniform fashion to a surface of the rotating substrate.

29. An assembly as claimed in claim 28, and wherein each of the elongated reactant delivery channels deliver an amount of reactant material which is appropriate to the speed of rotation of the substrate which is positioned therebeneath.

30. An assembly as claimed in claim 28, and wherein the pedestal imparts heat energy to the substrate.

31. An assembly as claimed in claim 30, and wherein the pedestal has a heating element which is selected from the group comprising resistive heating elements; coil inductive heating elements; and lamp heating elements.

32. An assembly as claimed in claim 29, and wherein the plurality of reactant delivery channels extend substantially radially outwardly from the central region in the direction of the peripheral edge thereof.

33. An assembly as claimed in claim 29, and wherein the plurality of reactant delivery channels are oriented in substantially equally spaced relation on the delivery member.

34. An assembly as claimed in claim 29, and wherein each of the substantially elongated reactant delivery channels is defined by a fluid distribution passageway having a substantially constant inside diametral dimension, and an elongated slot which communicates with same, and wherein the respective elongated slots have a diminishing depth dimension when measured from the first end, and in the direction of the second end of each of the elongated reactant delivery channels, and a width dimension.

35. An assembly as claimed in claim 34, and wherein each of the elongated delivery channels have similar dimensions.

36. An assembly as claimed in claim 34, and wherein each of the elongated delivery channels have dissimilar dimensions.

37. An assembly as claimed in claim 34, and wherein the respective slots have a transverse dimension which is substantially uniform.

38. An assembly as claimed in claim 34, and wherein the respective slots have a transverse dimension which is variable.

39. An assembly as claimed in claim 28, and wherein a reaction cavity is formed in the delivery member and the respective reactant delivery channels are coupled in fluid flowing relation relative to the reaction cavity.

40. An assembly as claimed in claim 28, and further comprising a plurality of purging gas passageways which are formed in the delivery member.

41. An assembly as claimed in claim 40, and wherein the respective purging gas passageways have a substantially constant transverse dimension.

42. An assembly as claimed in claim 40, and wherein the respective purging gas passageways have a transverse dimension which is variable.

43. An assembly for delivering a reactant material to a rotating substrate, comprising:
a plurality of reactant materials which, when chemically reacted together, form a resulting product which is delivered to a surface of a rotating substrate; and
a delivery member coupled in fluid flowing relation relative to the respective reactant materials, and positioned above the rotating substrate, and wherein the delivery member delivers the respective reactant materials into a chemical reaction zone which is located therebetween the delivery member and the rotating substrate, and in a manner where the resulting product is chemically produced in the chemical reaction zone following the release of the reactant materials from the delivery member, and wherein the delivery member is arranged so as to deliver a variable amount of reactant materials which results in the generation of an amount of the resulting product which is correlated to the speed of rotation of a region of the rotating substrate which is positioned therebeneath the delivery member to cause a substantially uniform deposition of the resulting product on the surface of the rotating substrate.

44. An assembly as claimed in claim 43, and wherein the delivery member has a central region and a peripheral edge, and wherein the delivery member further comprises a plurality of complementary groups of substantially continuous, elongated delivery channels which radiate in opposite directions from the central region.

45. An assembly as claimed in claim 44, and wherein the complementary groups of elongated delivery channels are substantially equally positioned upon the delivery member.

46. An assembly as claimed in claim 44, and wherein each of the elongated reactant delivery channels has a first end which is located in the central region and an opposite second end which is located near the peripheral edge of the delivery member, and wherein the first end of the complementary pairs are each coupled in fluid flowing relation relative to one of the plurality of reactant materials.

47. An assembly as claimed in claim 46, and wherein each of the elongated reactant delivery channels comprises a uniformly dimensioned fluid distribution passageway which extends between the first and second ends thereof, and an elongated slot which communicates with the fluid distribution passageway and which delivers the respective reactant materials into the reaction zone.

48. An assembly as claimed in claim 47, and wherein respective elongated slots extend substantially along the length of each of the fluid distribution passageways, and wherein each of the elongated slots have a depth dimension which diminishes when measured from the first end, and in the direction of the second end, and a width dimension.

49. An assembly as claimed in claim 47, and wherein each of the elongated slots have a substantially uniform depth dimension when measured from the first end, and in the direction of the second end.

50. An assembly as claimed in claim 47, and wherein the dimensions of the respective elongated slots are similar.

51. An assembly as claimed in claim 47, and wherein the dimensions of the respective elongated slots are dissimilar.

52. An assembly for delivering a reactant material to a substrate, comprising:
a fluid delivery member having a main body defined by a first surface; an opposite second surface; and a peripheral edge, and wherein the first surface defines a substantially centrally disposed reactant delivery region which is coupled in fluid flowing relation relative to a plurality of reactants which are to be delivered by the fluid delivery member to a chemical reaction zone which is located adjacent to the second surface of the fluid delivery member, and wherein the first surface is further defined by a plurality of structural members which extend radially outwardly relative to the centrally disposed reactant delivery region to the peripheral edge of the main body, and wherein the first surface further defines intermediate regions located therebetween the respective structural members, and wherein a plurality of passageways are formed in the intermediate regions and which facilitate the passage of a source of gas therethrough, and wherein a fluid distribution passageway is formed in each of the plurality of structural members, and wherein the fluid distribution passageway has a first end which is coupled in fluid flowing relation relative the centrally disposed reactant delivery region, and an opposite second end which is located near the peripheral edge, and wherein the fluid distribution passageway extends in an acutely angulated orientation therebetween the centrally disposed reactant delivery region, and the peripheral edge, and wherein the first end of the fluid distribution passageway is located near the first surface of the main body, and the second end of the fluid distribution passageway is located near the second surface thereof, and wherein an elongated slot, having a variable depth, is formed in the second surface of the main body, and which couples the fluid distribution passageways in fluid communication with the second surface, and wherein the elongated slot has a depth dimension which diminishes when measured from the first end of fluid distribution passageway, and in the direction of the second end of the fluid distribution passageway, and wherein reactants delivered to the centrally disposed reactant delivery region pass into the first end of the fluid distribution passageway, and then through the elongated slot, for subsequent delivery into the chemical reaction zone which is located adjacent to the second surface.

53. An assembly as claimed in claim 52, and wherein a plurality of fluid distribution passageways and corresponding elongated slots are formed in the main body.

54. An assembly as claimed in claim 53, and wherein the reactants exiting the respective elongated slots react together in the chemical reaction zone or on a surface of a substrate which is located in spaced relation relative to the second surface of the main body, to form a resulting product which is deposited on the surface of the substrate.

55. An assembly as claimed in claim 54, and wherein the assembly further comprises:
a rotating pedestal which supports the substrate in predetermined spaced, rotating relationship relative to the second surface of the main body.

56. An assembly as claimed in claim 55, and wherein the pedestal rotates the substrate at a predetermined rotational speed, and wherein the respective fluid distribution passageways and elongated slots are each dimensioned to deliver an amount of reactants into the chemical reaction zone so as to facilitate a chemical reaction which produces a resulting product which is deposited substantially uniformly across the surface of the substrate at the predetermined rotational speed.

57. A method for depositing a reactant material onto a surface of a substrate, comprising:
providing a rotating pedestal which supports a substrate in a substantially horizontal and rotational orientation;
providing sources of reactant materials which when chemically reacted together form a resulting product which is deposited onto the surface of the substrate;
providing a delivery member which has a plurality of elongated reactant delivery channels formed therein, and coupling the delivery member in fluid flowing relation relative to the sources of reactant materials;
positioning the substrate in spaced, rotating relation relative to the delivery member, and wherein a chemical reaction zone is defined therebetween the surface of the substrate and the delivery member; and
delivering a variable amount of the reactant materials by way of the elongated reactant delivery channels into the chemical reaction zone to produce an amount of the resulting product which is substantially uniformly deposited on the surface of the rotating substrate.

58. A method as claimed in claim 57, and wherein each of the respective reactant delivery channels further comprises:
an elongated fluid distribution passageway having opposite first and second ends; and
an elongated slot which is coupled in fluid flowing relation relative to the fluid distribution passageway, and wherein the elongated slot has a depth dimension which diminishes when measured from the first end and in the direction of the second end of the fluid distribution passageway.

59. A method as claimed in claim 57, and wherein the respective reactant delivery channels further comprise:
an elongated slot which is coupled in fluid flowing relation relative to the fluid distribution passageway, and which has a substantially uniform depth dimension when measured from the first end and in the direction of the second end of the fluid distribution passageway.

60. An assembly for delivering a reactant material to a substrate, comprising:
a delivery member having opposite first and second surfaces, and wherein the second surface is positioned adjacent to a substrate, and wherein a substantially continuous fluid distribution passageway is formed in the delivery member and is further coupled in fluid flowing relation relative to a source of reactant material, and wherein a plurality of reactant delivery passageways are formed in the second surface and extend in the direction of the first surface, and which are coupled in fluid flowing relation relative to the continuous fluid distribution passageway, and wherein the respective reactant delivery passageways deliver the reactant material in amounts which facilitate a deposit of a substantially uniform amount of the reactant material on the adjacent substrate.

61. An assembly as claimed in claim 60, and wherein the plurality of reactant delivery passageways each have a substantially similar transverse dimension.

62. An assembly as claimed in claim 60, and wherein the plurality of reactant delivery passageways each have a dissimilar transverse dimension.

63. An assembly as claimed in claim 61, and wherein the delivery member has a central region, and wherein the distance between the reactant delivery passageways decreases when measured from the central region, and in the direction of the peripheral edge.

64. An assembly as claimed in claim 62, and wherein the delivery member has a central region, and wherein the transverse dimension of the respective reactant delivery passageways increases when measured from the central region, and in the direction of the peripheral edge.

65. An assembly as claimed in claim 60, and wherein the delivery member has a central region, and wherein the respective reactant delivery passageways have a substantially similar length dimension.

66. An assembly as claimed in claim 60, and wherein the delivery member has a central region, and wherein the respective reactant delivery passageways have a diminishing length dimension when measured from the central region and in the direction of the peripheral edge of the delivery member.

67. An assembly as claimed in claim 60, and wherein the substantially continuous fluid distribution passageway comprises a plurality of fluid distribution passageways which are each coupled in fluid flowing relation relative to a different source of reactant material.

68. An assembly as claimed in claim 60, and further comprising a support member having an upwardly facing surface, and which rotatably supports the substrate in adjacent, spaced relation relative to the delivery member, and wherein the amount of reactant material delivered by the respective reactant material passageways is correlated to the speed of rotation of the substrate.
